(19) United States
(12) Patent Application Publication
(10) Pub. No.: US 2009/0091260 A1
(43) Pub. Date: Apr. 9, 2009

(54) Protective layer, method of manufacturing the same, and plasma display panel including the same

(76) Inventor: Joe-Oong Hahn, Suwon-si (KR)

Correspondence Address: LEE & MORSE, P.C.;Attorney and Counselors At Law, SUITE 500, 3141 FAIRVIEW PARK DRIVE, FALLS CHURCH, VA, 22042, US

(21) Appl. No.: 12/232,656

(22) Filed: Sep. 22, 2008

(30) Foreign Application Priority Data
Oct. 8, 2007 (KR) 10-2007-0100866

(51) Int. Cl. H01J 17/00; B22F 7/02; C23C 16/00

(52) U.S. Cl. 313/581; 428/548; 427/248.1

(57) ABSTRACT

A protective layer for a plasma display panel (PDP) includes a single layer having a first magnesium oxide crystal doped with a first impurity and a second magnesium oxide crystal doped with a second impurity.

### BACKGROUND OF THE INVENTION

1. Field of the Invention

Embodiments of the present invention relate to a protective layer for a plasma display panel having improved wall charge retention capabilities and enhanced secondary electron emission characteristics.

2. Description of the Related Art

Plasma display panels (PDPs) may refer to flat display panels exhibiting improved structure, e.g., large and thin screens, and enhanced display properties, e.g., high brightness, high contrast, wide viewing angle, wide color reproduction range, and so forth. The PDPs may display images via a gas discharge phenomenon. In particular, PDPs may generate vacuum ultraviolet (VUV) light by applying a high-frequency voltage to a discharge gas, so the VUV light may trigger light emission from a photoluminescent material to form an image.

A conventional PDP may include electrodes and the photoluminescent material between two substrates. The conventional PDP may further include a protective layer between the substrates to shield, e.g., the electrodes. An increase of secondary electron emission characteristics in the conventional protective layer, however, may reduce charge retention capabilities therein, and therefore, may cause malfunction of the PDP.

### SUMMARY OF THE INVENTION

Embodiments of the present invention are therefore directed to a protective layer, a method of manufacturing the same, and a PDP including the same, which substantially overcome one or more of the disadvantages and shortcomings of the related art.

It is therefore a feature of an embodiment of the present invention to provide a protective layer having both excellent secondary electron emission characteristics and superior wall charge retention capabilities.

It is therefore another feature of an embodiment of the present invention to provide a method of manufacturing a protective layer having both excellent secondary electron emission characteristics and superior wall charge retention capabilities.

It is yet another feature of an embodiment of the present invention to provide a PDP including a protective layer having both excellent secondary electron emission characteristics and superior wall charge retention capabilities.

At least one of the above and other features and advantages of the present invention may be realized by providing a protective layer for a PDP, including a single layer having a first magnesium oxide crystal doped with a first impurity and a second magnesium oxide crystal doped with a second impurity. The second magnesium oxide crystal may have a different crystal state than the first magnesium oxide crystal. The first impurity may be different from the second impurity. The first impurity may include a material functioning as an electron trap. The first impurity may include one or more of scandium, silicon, and/or germanium. The second impurity may include a material functioning as a hole trap. The second impurity may include one or more of chromium, lithium, and/or sodium. An amount of the first impurity in the first magnesium oxide crystals may be about 100 ppm to about 1000 ppm. A weight ratio of the first impurity to the second impurity in the protective layer may be about 1:0.01 to about 1:1.

At least one of the above and other features and advantages of the present invention may be also realized by providing a method of manufacturing a protective layer for a PDP, including doping first magnesium oxide crystals with a first impurity to form first pellets, and doping second magnesium oxide crystals with a second impurity to form second pellets, and depositing the first and second pellets to form a single layer. Depositing the first and second pellets may include simultaneous deposition of the first and second pellets. The method may further include mixing the first and second pellets before depositing the first and second pellets.

At least one of the above and other features and advantages of the present invention may be further realized by providing a PDP, including a first substrate facing a second substrate, barrier ribs between the first and second substrates, a plurality of electrodes between the first and second substrates, and a protective layer having a single layer structure between the first and second substrates, the protective layer including a first magnesium oxide crystal doped with a first impurity and a second magnesium oxide crystal doped with a second impurity. The first impurity may include a material functioning as an electron trap. The second impurity may include a material functioning as a hole trap. The plurality of electrodes may include pairs of sustain discharge electrodes on the first substrate and address electrodes on the second substrate. The PDP may further include a dielectric layer between the first and second substrates, the protective layer being on the dielectric layer. The dielectric layer may be between the first substrate and the protective layer. The PDP may further include a second dielectric layer on the second substrate.

### BRIEF DESCRIPTION OF THE DRAWINGS

The above and other features and advantages of the present invention will become more apparent to those of ordinary skill in the art by describing in detail exemplary embodiments thereof with reference to the attached drawings, in which:

FIG. 1 illustrates an exploded perspective view of a PDP according to an embodiment of the present invention;

FIG. 2 illustrates a cross-sectional view along line II-II of the PDP of FIG. 1;

FIG. 3 illustrates a SEM image of a protective layer according to an embodiment of the present invention;

FIGS. 4A-4B illustrate graphs of wall charge retention capabilities of protective layers of Example 1 and Comparative Example 1, respectively; and

FIG. 5 illustrates a graph of secondary electron emission characteristics of a protective layer of Example 1.

### DETAILED DESCRIPTION OF THE INVENTION

Korean Patent Application No. 10-2007-0100866, filed on Oct. 8, 2007, in the Korean Intellectual Property Office, and entitled: “Protective Layer, Method of Manufacturing the Protective Layer, and Plasma Display Panel Comprising the Protective Layer,” is incorporated by reference herein in its entirety.

Embodiments of the present invention will now be described more fully hereinafter with reference to the accompanying drawings, in which exemplary embodiments of the invention are illustrated. Aspects of the invention may, however, be embodied in different forms and should not be construed as limited to the embodiments set forth herein. Rather, these embodiments are provided so that this disclosure will be thorough and complete, and will fully convey the scope of the invention to those skilled in the art.

In the figures, the dimensions of layers, elements, and regions may be exaggerated for clarity of illustration. It will also be understood that when a layer or element is referred to as being “on” another layer, element, or substrate, it can be directly on the other layer, element, or substrate, or intervening layers and/or elements may also be present. Further, it will be understood that when a layer or element is referred to as being “under” another layer or element, it can be directly under, or one or more intervening layers and/or elements may also be present. In addition, it will also be understood that when a layer or element is referred to as being “between” two layers or elements, it can be the only layer or element between the two layers or elements, or one or more intervening layers and/or elements may also be present. Like reference numerals refer to like elements throughout.

A protective layer according to an embodiment of the present invention may have a single-layered structure, and may include magnesium oxide (MgO). In particular, the protective layer may include first magnesium oxide crystals doped with a first impurity and second magnesium oxide crystals doped with a second impurity. Magnesium oxide may exhibit excellent plasma resistance and high light transmissivity. Accordingly, when the protective layer of the present invention is used in, e.g., a plasma display panel, transmission of visible light through the protective layer, e.g., light generated by photoluminescent materials to form images on a screen, may be facilitated.

The first and second magnesium oxide crystals may be at different crystal states, and the first and second impurities may be different from each other. The first magnesium oxide crystals with the first impurity and the second magnesium oxide crystals with the second impurity may be present in the single-layered structure of the protective layer simultaneously. Accordingly, the protective layer may include a single layer of magnesium oxide having magnesium oxide crystals at different crystal states and with different impurities.

The first impurity in the first magnesium oxide crystals may be in an amount of about 100 ppm to about 1000 ppm with respect to the first magnesium oxide crystals. The first impurity may include a material capable of functioning as an electron trap. Examples of the first impurity may include one or more of scandium (Sc), silicon (Si), and/or germanium (Ge). Accordingly, the first magnesium oxide crystals with the first impurity may exhibit excellent secondary electron emission characteristics, i.e., characteristics related to voltage required to initiate discharge and voltage required to sustain discharge.

The second impurity in the second magnesium oxide crystals may be in an amount of about 100 ppm to about 1000 ppm with respect to the magnesium oxide crystals. The second impurity may include a material capable of functioning as a hole trap. Examples of the second impurity may include one or more of chromium (Cr), lithium (Li), and/or sodium (Na). Accordingly, the second magnesium oxide crystals with the second impurity may exhibit superior wall charge retention capabilities.

The first magnesium oxide crystals with the first impurity and the second magnesium oxide crystals with the second impurity may coexist in different crystal states in a single layer. Crystal states of the first and second magnesium oxides may be determined with respect to energy levels of the first and second magnesium oxides, respectively. Thus, the first magnesium oxide crystals doped with the first impurity may improve secondary electron emission characteristics, and the second magnesium oxide crystals doped with the second impurity may improve wall charge retention capabilities.

A weight ratio of the first impurity to the second impurity in the protective layer may be in the range of about 1:0.01 to about 1:1. For example, the protective layer may include the first impurity to the second impurity in a weight ratio of about 1:0.2. An increase in an amount of the first impurity in the protective layer may increase secondary electron emission characteristics therein. An increase in an amount of the second impurity in the protective layer may increase wall charge retention capabilities therein, while decreasing secondary electron emission characteristics in the protective layer. Thus, the weight ratio of the first impurity to the second impurity in the protective layer may be optimized to provide both improved secondary electron emission characteristics and enhanced wall charge retention capabilities. Further, the weight ratio may be adjusted with respect to different magnesium oxide crystals, e.g., crystal states, and/or different impurities.

The protective layer according to embodiments of the present invention may be advantageous in providing both excellent electron emission characteristics and superior wall charge accumulation capabilities. In particular, when magnesium oxide crystals of a single crystal state are doped with both the first and second impurities, the first and second impurities may not function both as electron traps and hole traps in the single crystal state of the magnesium oxide crystals. The protective layer according to embodiments of the present invention, however, may include the first and second impurities in different crystal states of the magnesium oxide crystals. A protective layer having a first impurity in first magnesium oxide crystals of one crystal state coexisting with a second impurity in second magnesium oxide crystals of a different crystal state in a single layer may cause the first and second impurities to function as electron traps and hole traps, respectively. When the first and second impurities function both as electron traps and hole traps, respectively, in a single layer, both electron emission characteristics and wall charge accumulation capabilities of the layer may be substantially improved.

A method of manufacturing the protective layer may be as follows. The first magnesium oxide crystals may be doped with the first impurity to form first pellets. The second magnesium oxide crystals may be doped with the second impurity to form second pellets. The first and second pellets may be used to form the protective layer.

More specifically, high purity magnesium oxide powder may be mixed with another powder including the first impurity, a binder, and an organic solvent to form a first mixture. For example, if the first impurity is scandium, scandium salt, e.g., scandium oxide (Sc₂O₃) or scandium nitrate (Sc(NO₃)₃), may be used. The binder may include, e.g., one or more of polyethylene glycol, polyvinyl butyral, or the like. The organic solvent may include, e.g., one or more of ethanol, propanol, or the like. The first mixture may be heated at a temperature of about 400° C. to about 500° C. Then, the heated first mixture may be sintered at a temperature of about 1000° C. to about 2000° C. to form the first pellets. The method of forming the second pellets may be substantially similar to the method of forming the first pellets, with the exception of using a powder including the second impurity instead of the first impurity. For example, if the second impurity is chromium, chromium salt, e.g., chromium oxide (Cr₂O₃) or chromium nitrate (Cr(NO₃)₃), may be mixed with the high purity magnesium oxide powder, binder, and organic solvent to form a second mixture for the second pellets. The first and second pellets may include magnesium oxide crystals at different crystal states.

The first and second pellets may be deposited simultaneously by a co-deposition method to form a single layer and to selectively grow crystals. Examples of co-deposition methods may include a co-evaporation method, a co-sputtering method, a co-ion plating method, and so forth.

Alternatively, a co-pellet including both the first and second magnesium oxide crystals may be deposited, e.g., by evaporation, sputtering, ion plating, and so forth, to grow a single layer including both the first and second magnesium oxide crystals. The co-pellet may be formed by preparing first granules with the first impurity and second granules with the second impurity, and by placing the first and second granules in a mold under a predetermined pressure to form the co-pellet.

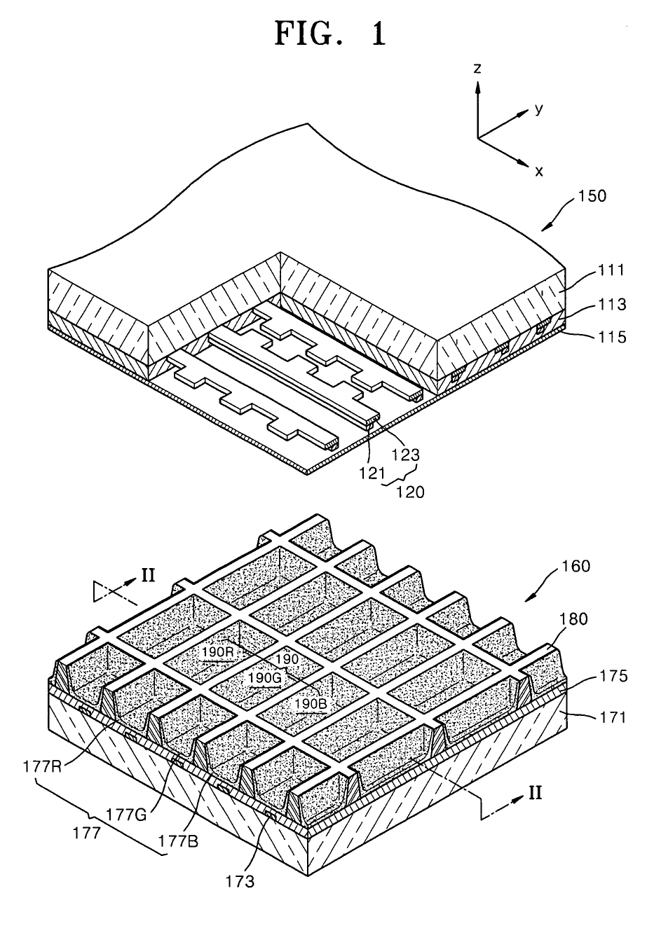

FIGS. 1-2 illustrate perspective and cross-sectional views, respectively, of a PDP according to an embodiment of the present invention. Referring to FIGS. 1-2, the PDP may include upper and lower panels 150 and 160 facing one another. The upper panel 150 may include a plurality of sustain discharge electrodes 120 along a first direction, e.g., along the x-axis, a first dielectric layer 113, and a protective layer 115 on a first substrate 111. The lower panel 160 may include a plurality of address electrodes 173 along a second direction, e.g., along the y-axis, a second dielectric layer 175, and barrier ribs 180 on a second substrate 171. The protective layer 115 in the upper panel 150 may be formed according to embodiments of the present invention as described previously, and therefore, its detailed description will not be repeated. The protective layer 150 may increase lifetime of the PDP and lower voltage required to initiate discharge with a high secondary electron emission coefficient.

The first and second substrates 111 and 171 of the PDP may face each other, and may be formed of any material having excellent light permeability, e.g., a soda lime glass. The first and/or second substrates 111 and 171 may be colored in order to reduce reflection of external light, so bright room contrast may be improved.

The sustain discharge electrodes 120 of the PDP may be parallel to each other. The sustain discharge electrodes 120 may include pairs of X and Y electrodes, e.g., in an alternating pattern. Each X and Y electrode may include a transparent electrode 123 and a bus electrode 121. The transparent electrodes 123 may be formed of a material having high visible light transmissivity and low electrode resistance, e.g., indium tin oxide. The bus electrodes 121 may be formed on the transparent electrode to face the second panel 160, and may be formed of, e.g., chromium (Cr), copper (Cu), and aluminum (Al). The bus electrodes 121 may compensate for a relatively large resistance of the transparent electrodes 123, so a substantially uniform voltage may be applied to a plurality of discharge cells 190 between the first and second panels 150 and 160. Voltage may be applied to the transparent electrodes 123 to generate and sustain a discharge in the discharge cells 190.

The first dielectric layer 113 may be formed to cover the sustain discharge electrodes 120, so the sustain discharge electrodes 120 may be between the first substrate 111 and the first dielectric layer 113. In the first dielectric layer 113, discharge current may be restricted in order to sustain glow discharge, and memory function and voltage may be reduced by wall charge accumulation. Withstand voltage and visible light transmissivity may be high in order to increase discharge efficiency.

The address electrodes 173 of the PDP may be parallel to each on the second substrate 171. The address electrode 173 may be formed of a conductive material, e.g., Cr, Cu, and/or Al, to provide a substantially uniform voltage to the discharge cells.

The second dielectric layer 175 of the PDP may be formed to cover the address electrodes 173, so the address electrodes 173 may be between the second substrate 171 and the second dielectric layer 175. Accordingly, the address electrodes 173 may be shielded from collisions with charged particles. In the second dielectric layer 175, discharge current may be restricted in order to sustain glow discharge, and memory function and voltage may be reduced by wall charge accumulation.

The barrier ribs 180 of the PDP may be formed on the second dielectric layer 175 to partition a discharge space between the first and second substrates 111 and 171 into the discharge cells 190. The barrier ribs 180 may be arranged in any suitable pattern, so the discharge cells 190 may form, e.g., a matrix. The discharge cells 190 may have any suitable cross-section, e.g., a circle, a quadrangle, or any other polygon. The discharge cells 190 may include photoluminescent layers 177 therein. More specifically, a photoluminescent layer 177, e.g., a fluorescent layer, may be disposed in each of the discharge cells 190. For example, red, green, and blue photoluminescent layers 177R, 177G, and 177B may be alternately deposited in the discharge cells 190 to form red, green, and blue discharge cells 190R, 190G, and 190B, respectively. A discharge gas, e.g., one or more of neon (Ne), xenon (Xe), and/or helium (He), may be injected into the discharge cells 190.

### EXAMPLES

### Example 1

a protective layer according to an embodiment of the present invention was prepared as follows. First, high purity magnesium oxide powder (MgO, 99.995%) was mixed with high purity scandium salt powder (Sc₂O₃, 99.999%), polyethylene glycol, and ethanol to form a first mixture. The scandium salt powder was used in an amount of 200 ppm with respect to the magnesium oxide powder. The first mixture was heated at a temperature of 450° C. and sintered at a temperature of 1650° C. to form first pellets.

Next, high purity magnesium oxide powder (MgO, 99.995%) was mixed with high purity chromium salt powder (Cr₂O₃, 99.999%), polyethylene glycol, and ethanol to form a second mixture. The chromium salt powder was used in an amount of 100 ppm with respect to the magnesium oxide powder. The second mixture was heated to at a temperature of 450° C. and sintered at a temperature of 1650° C. to form the second pellet. Equal amounts of solvent were used to prepare the first and second pellets.

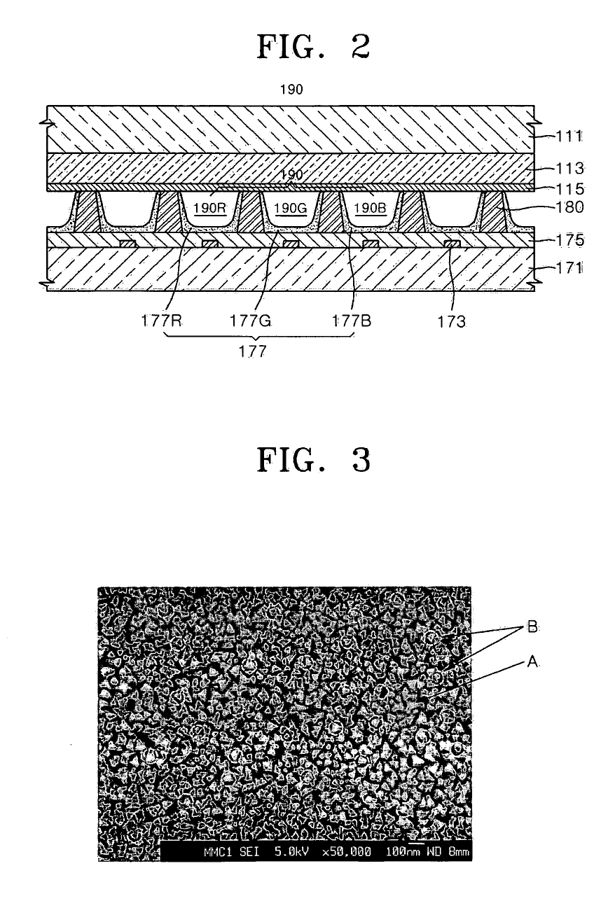

Next, the first and second pellets were mixed to form a co-pellet. The weight ratio of the scandium salt powder to the chromium salt powder in the co-pellet was 1:0.2. The co-pellet was deposited to form a single-layered protective layer. The co-pellet was deposited as a single-layered protective layer on a first substrate including a dielectric layer and sustain discharge electrodes. A scanning electron microscope (SEM) image of the formed protective layer is illustrated in FIG. 3. The separate first and second magnesium oxide crystals in the formed protective layer are indicated by (A) and (B), respectively, in FIG.

### Comparative Example 1

magnesium oxide powder (MgO, 99.995%) was mixed with silicon powder (Si, 99.999%) to form a third mixture. The third mixture was deposited to form a protective layer having a single impurity in magnesium oxide crystals at a single crystal state.

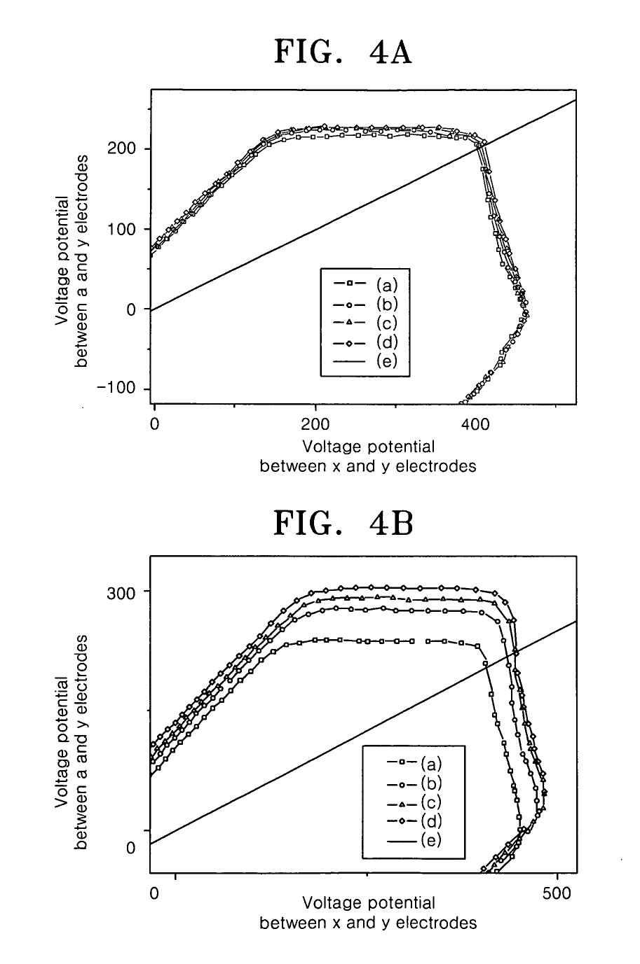

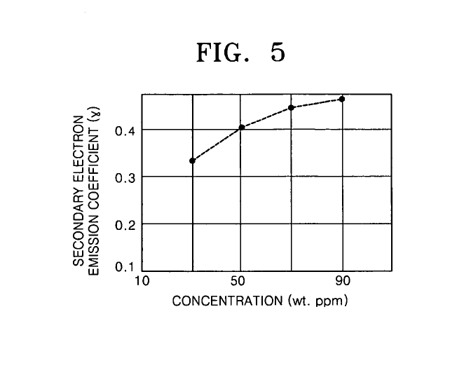

The protective layers of Example 1 and Comparative Example 1 were compared in terms of wall charge retention capabilities. Results are illustrated in FIGS. 4A-4B. In addition, the protective layer of Example 1 was evaluated in terms of secondary electron emission characteristics. Results are illustrated in FIG. 5.

More specifically, the protective layers of Example 1 and Comparative Example 1 were incorporated into substantially identical PDPs, followed by application of a sustain voltage of 300 V to the X and Y electrodes and measurement of a voltage transfer curve (VTC). During application of the sustain voltage of 300 V, voltage potential between address (a) electrodes and respective Y electrodes was measured with respect to voltage potential between respective Y and X electrodes during a period of at least 2000 μs to determine voltage due to wall charge retention. Curves (a)-(d) in FIGS. 4A-4B correspond to scan times of 50 μs, 500 μs, 1000 μs, and 2000 μs, respectively. As a control group, curve (e) was obtained by floating the address electrodes.

As illustrated in the graphs of FIGS. 4A-4B, the VTC of Example 1, as compared to the Comparative Example 1, exhibited an improved wall charge retention capability. In particular, as illustrated in FIG. 4B, the voltage potential in Comparative Example 1 between the address and Y electrodes during a period of about 2000 μs varied to have a value greater than about 80 V, so a loss of wall charges was indicated. In contrast, as illustrated in FIG. 4A, a voltage potential in Example 1 between the address and Y electrodes during a period of about 2000 μs was very small, i.e., curves (a)-(d) were substantially close to each other. Thus, it can be seen that wall charge retention capabilities were increased in Example 1, as compared to Comparative Example 1.

The protective layer of Example 1 was evaluated in terms of secondary electron emission characteristics by varying the amount of scandium (Sc) therein, followed by measurement of a secondary electron emission coefficient. A weight of Sc was varied from about 30 ppm of Sc in the first magnesium oxide pellet to about 90 ppm of Sc in the first magnesium oxide pellet. As illustrated in FIG. 5, secondary electron emission coefficient increased according to an increased amount of Sc. Thus, it can be seen that a protective layer formed according to embodiments of the present invention may have improved secondary electron emission characteristics in addition to enhanced wall charge retention capabilities.

As described above, a protective layer according to embodiments of the present invention may exhibit both superior wall charge retention capabilities and excellent secondary electron emission characteristics. Further, the present invention may provide a method of effectively preparing a single-layered protective layer using a deposition of a co-pellet of different magnesium oxide crystals doped with different impurities or a co-deposition of two pellets of different magnesium oxide crystals doped with different impurities. The protective layer according to embodiments of the present invention may be advantageous in providing a substantially minimized waste of power consumption and reduced address discharge time by increasing a secondary electron emission coefficient and improving wall charge retention capabilities. Thus, a PDP having improved reliability and productivity may be produced.

Exemplary embodiments of the present invention have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A protective layer for a plasma display panel (PDP), comprising a single layer having a first magnesium oxide crystal doped with a first impurity and a second magnesium oxide crystal doped with a second impurity.

2. The protective layer as claimed in claim 1, wherein the second magnesium oxide crystal has a different crystal state than the first magnesium oxide crystal.

3. The protective layer as claimed in claim 1, wherein the first impurity is different from the second impurity.

4. The protective layer as claimed in claim 3, wherein the first impurity includes a material functioning as an electron trap.

5. The protective layer as claimed in claim 4, wherein the first impurity includes one or more of scandium, silicon, and/or germanium.

6. The protective layer as claimed in claim.3, wherein the second impurity includes a material functioning as a hole trap.

7. The protective layer as claimed in claim 6, wherein the second impurity includes one or more of chromium, lithium, and/or sodium.

8. The protective layer as claimed in claim 1, wherein an amount of the first impurity in the first magnesium oxide crystal is about 100 ppm to about 1000 ppm.

9. The protective layer as claimed in claim 1, wherein a weight ratio of the first impurity to the second impurity in the protective layer is about 1:0.01 to about 1:1.

10. A method of manufacturing a protective layer for a plasma display panel (PDP), comprising:
doping first magnesium oxide crystals with a first impurity to form first pellets;
doping second magnesium oxide crystals with a second impurity to form second pellets; and
depositing the first and second pellets to form a single layer.

11. The method as claimed in claim 10, wherein depositing the first and second pellets includes simultaneous deposition of the first and second pellets.

12. The method as claimed in claim 10, further comprising mixing the first and second pellets before depositing the first and second pellets.

13. A plasma display panel (PDP), comprising:
a first substrate facing a second substrate;
barrier ribs between the first and second substrates;
a plurality of electrodes between the first and second substrates; and
a protective layer between the first and second substrates, the protective layer having a single layer structure including a first magnesium oxide crystal doped with a first impurity and a second magnesium oxide crystal doped with a second impurity.

14. The PDP as claimed in claim 13, wherein the first impurity includes a material functioning as an electron trap.

15. The PDP as claimed in claim 13, wherein the second impurity includes a material functioning as a hole trap.

16. The PDP as claimed in claim 13, wherein the plurality of electrodes includes pairs of sustain discharge electrodes on the first substrate and address electrodes on the second substrate.

17. The PDP as claimed in claim 16, further comprising a dielectric layer between the first and second substrates, the protective layer being on the dielectric layer.

18. The PDP as claimed in claim 17, wherein the dielectric layer is between the first substrate and the protective layer.

19. The PDP as claimed in claim 18, further comprising a second dielectric layer on the second substrate.
